(19) United States
(12) Patent Application Publication
(10) Pub. No.: US 2006/0012958 A1
(43) Pub. Date: Jan. 19, 2006

(54) Electronic apparatus

(75) Inventors: Kentaro Tomioka, Sayama-shi (JP); Katsumi Hisano, Kashiwa-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: Kabushiki Kaisha Toshiba

(21) Appl. No.: 11/231,761

(22) Filed: Sep. 22, 2005

Related U.S. Application Data
(62) Division of application No. 10/650,718, filed on Aug. 29, 2003.

(30) Foreign Application Priority Data
Aug. 30, 2002 (JP) 2002-255544

(51) Int. Cl. H05K 7/20

(52) U.S. Cl. 361/699; 361/687

(57) ABSTRACT

An electronic apparatus includes a heat-generating component, a heat receiving portion thermally connected to the heat-generating component, a heat radiating portion to radiate heat generated y the heat-generating component, and a circulation path to circulate a liquid coolant between the heat receiving and radiating portions. The heat radiating portion has a circulation passage defined therein, a first region including a coolant inlet port, and a second region including a coolant outlet port. The circulation passage has first and second circulation passages. The first circulation passage extends from the coolant inlet port in the first region to a position distant from the coolant inlet port, and reaches the second region after passing beside the coolant inlet port again. The second circulation passage extends between the first circulation passage and the coolant outlet port in the second region.

### CROSS-REFERENCE TO RELATED APPLICATIONS

This application is based upon and claims the benefit of priority from the prior Japanese Patent Application No. 2002-255544, filed Aug. 30, 2002, the entire contents of which are incorporated herein by reference.

### BACKGROUND OF THE INVENTION

1. Field of the Invention

The present invention relates to an electronic apparatus housing therein a heat-generating component, such as a semiconductor package, and more particularly, to an electronic apparatus having a cooling structure for enhancing the cooling performance of the heat-generating component.

2. Description of the Related Art

Portable electronic apparatuses, such as notebook-type portable computers and mobile communications equipment, are provided with microprocessors for processing multimedia information. Higher processing speeds and the development of highly multifunctional versions of the microprocessors of this type have entailed rapid increase of the heat release value during operation. In order to ensure stable operation of the microprocessors, therefore, the heat radiating capability of the microprocessors must be enhanced.

To cope with this, a conventional electronic apparatus is furnished with an air-cooling device for compulsorily cooling the microprocessor. The cooling device comprises a heat sink that absorbs heat from the microprocessor and an electric fan that blows air over the heat sink.

The heat sink has a heat receiving portion that receives heat from the microprocessor, a plurality of radiating fins, and an air passage. The air passage is defined extending along the heat receiving portion and the radiating fins. An electric fan blows air through the air passage. The air compulsorily cools the heat sink as it flows between the radiating fins. Thus, the heat from the microprocessor transmitted to the heat sink is removed by the flow of air and discharged to the outside of the electronic apparatus through the lower-stream end of the passage.

According to this conventional cooling system, the air that flows through the air passage serves as a cooling medium that removes heat from the microprocessor. Thus, the cooling performance of the microprocessor substantially depends on the amount of airflow, and the area of contact between the airflow and the heat sink.

If the airflow is increased to improve the cooling performance of the microprocessor, however, the rotational frequency of the electric fan must be increased, so that substantial noises are produced inevitably. If the radiating fins are increased in number or in size, moreover, the heat sink becomes bulky and requires a wide installation space in the electronic apparatus. Therefore, this configuration cannot be applied to small-sized electronic apparatuses, such as portable computers.

Microprocessors for electronic apparatuses are expected to be further speeded up and given more functions in the near future. Accordingly, the amount of heat released from the microprocessors is expected to increase drastically. Presumably, therefore, microprocessors cannot be sufficiently cooled by conventional forced air-cooling systems.

To solve this problem, a so-called liquid-cooling system is described in Jpn. Pat. Appln. KOKAI Publication No. 7-142886, for example. In this system, a liquid that is much higher than air in specific heat is used as a coolant to enhance the ability to cool efficiency the microprocessor.

According to this novel cooling system, a heat receiving head is set in a casing that contains the microprocessor, and a radiating header is set in a display unit that is supported on the casing. The heat receiving head is thermally connected to the microprocessor. A passage through which a liquid coolant flows is defined in the heat receiving head. The radiating header is thermally connected to the display unit, and a passage through which the liquid coolant flows is also defined in the radiating header. A circulation path through which the coolant is circulated connects the respective passages of the heat receiving head and the radiating header to each other.

According to this cooling system, heat from the microprocessor is transmitted form the heat receiving head to the coolant and then transferred to the radiating header as the coolant flows. The heat transferred to the radiating header is diffused by thermal conduction as the coolant flows through the passage, and is discharged from the radiating header into the atmosphere through the display unit.

Thus, the heat from the microprocessor can be efficiently transferred to the display unit by utilizing the flow of the coolant. In consequence, the cooling performance of the microprocessor can be made higher than in the case of the conventional forced air-cooling, and there is no noise problem.

If the radiating header is set in the display unit, in an electronic apparatus that uses the cooling system described above, it is situated adjacent to a liquid crystal display panel. If the radiating header is heated to a temperature higher than the display panel can tolerate, the display panel is thermally damaged, thus the reliability of the electronic apparatus inevitably lowers. Thus, the radiating header should be able to discharge heat efficiently without adversely affecting other components of the apparatus.

In the cooling system described above, moreover, the coolant circulates in the electronic apparatus. If water or an antifreeze solution for use as the coolant leaks out, therefore, it may damage electronic components in the apparatus. If the leaked coolant further leaks out of the apparatus, it may cause alarm to the user. In some cases, the coolant may contact the user's body or clothes, thereby causing problems.

### BRIEF SUMMARY OF THE INVENTION

An electronic apparatus according to an embodiment of the invention comprises: a heat-generating component; a heat receiving portion thermally connected to the heat-generating component; a heat radiating portion to radiate heat generated by the heat-generating component; and a circulation path to circulate a liquid coolant between the heat receiving portion and the heat radiating portion. The heat radiating portion includes a circulation passage defined therein, a first region provided with a coolant inlet port and a second region provided with a coolant outlet port. The circulation passage of the heat radiating portion has a first circulation passage in the first region and a second circulation passage in the second region, the first circulation passage extending from the coolant inlet port to a position distant from the circulation inlet port and reaching the second region after passing beside the coolant inlet port again, and the second circulation passage extending between the first circulation passage and the coolant outlet port in the second region.

An electronic apparatus according to another embodiment of the invention comprises: a first casing; a heat-generating component arranged in the first casing; a heat receiving portion located in the first casing and thermally connected to the heat-generating component; a second casing connected to the first casing; a heat radiating portion to radiate-heat generated by the heat-generating component, the heat radiating portion being arranged in the second casing; and a circulation path to circulate a liquid coolant between the heat receiving portion and the heat radiating portion. The radiating plate includes a first region provided with a coolant inlet port and a second region provided with a coolant outlet port. The circulation passage in the radiating plate has a first circulation passage in the first region and a second circulation passage in the second region. The first circulation passage extends from the coolant inlet port to a position distant from the coolant inlet port and reaching the second region after passing beside the coolant inlet port again, and the second circulation passage extends between the first circulation passage and the coolant outlet port in the second region.

### BRIEF DESCRIPTION OF THE SEVERAL VIEWS OF THE DRAWING

The accompanying drawings, which are incorporated in and constitute a part of the specification, illustrate embodiments of the invention, and together with the general description given above and the detailed description of the embodiments given below, serve to explain the principles of the invention.

FIG. 1 is a perspective view of a portable computer according to a first embodiment of the invention with its display unit in an open position;

FIG. 2 is a sectional view showing the configuration of a cooling unit of the portable computer;

FIG. 3 is an exploded perspective view of a heat receiving head of the cooling unit;

FIG. 4 is a sectional view showing the positional relation between a semiconductor package and the heat receiving head of the portable computer;

FIG. 5 is a sectional view of the portable computer showing a path for a circulation pipe bestriding the boundary between the body and a display unit of the portable computer;

FIG. 6 is a sectional view of a radiator taken along line VI-VI of FIG. 2;

FIG. 7 is a sectional view of the radiator of the cooling unit showing a circulation passage configuration of the radiator;

FIG. 8 is a graph showing the relation between the area ratio between first and second regions of the radiator, cooling performance, and coolant temperature;

FIG. 9 is a sectional view showing a radiator of a portable computer according to a second embodiment of the invention;

FIG. 10 is a sectional view showing a radiator of a portable computer according to a third embodiment of the invention; and

FIG. 11 is a sectional view showing a portable computer according to a fourth embodiment of the invention.

### DETAILED DESCRIPTION OF THE INVENTION

Portable computers as electronic apparatuses according to embodiments of the present invention will now be described with reference to the accompanying drawings.

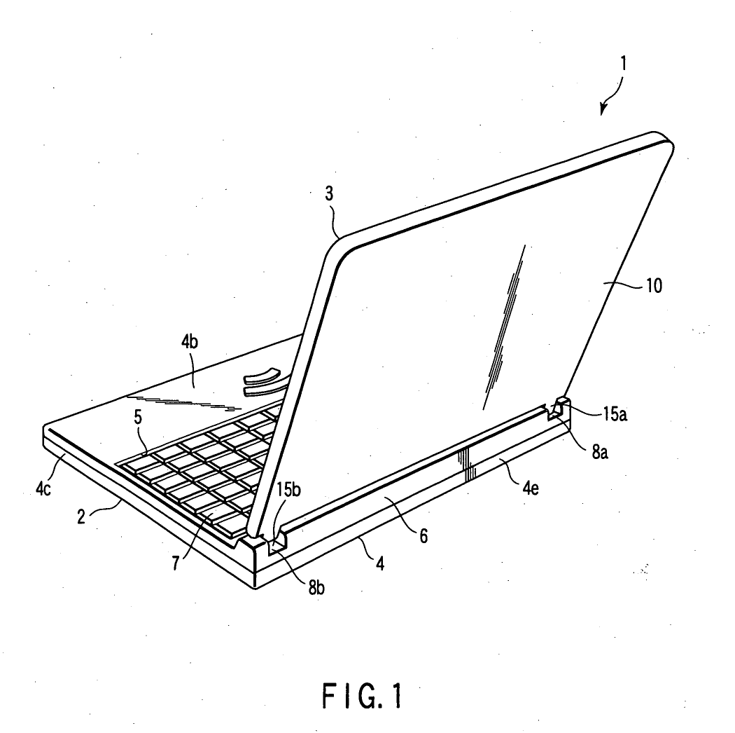

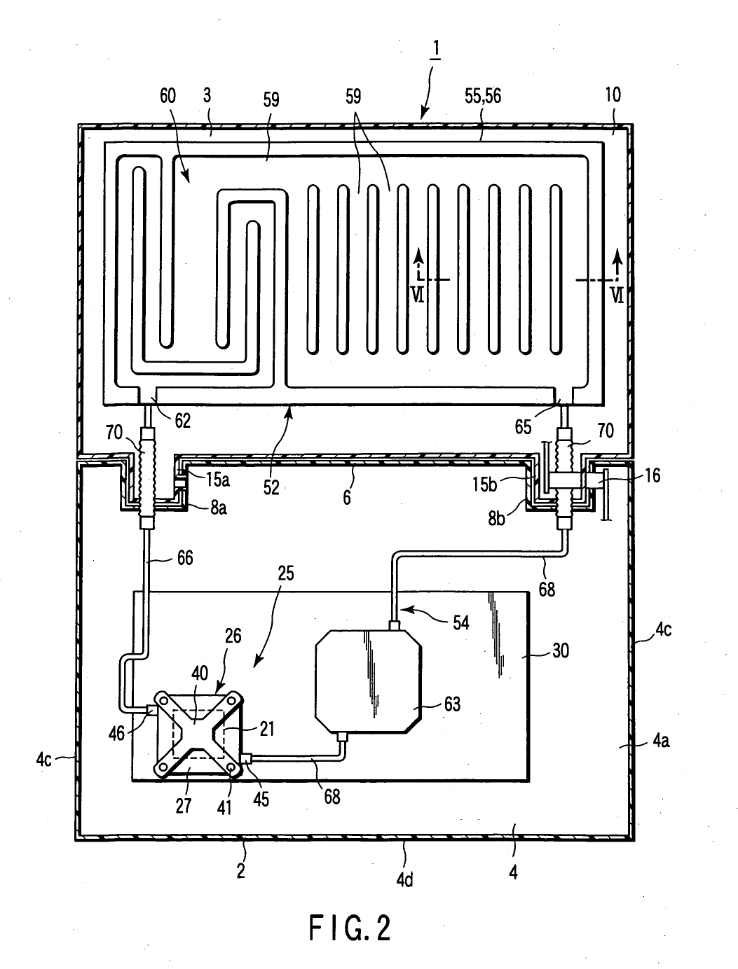

As shown in FIGS. 1 and 2, a portable computer 1 comprises an apparatus body 2 and a display unit 3 supported on the apparatus body 2. The apparatus body 2 is provided with a first casing 4 of a plastic material. The first casing 4 is a flat box that has bottom wall 4a, top wall 4b, left- and right-hand sidewalls 4c, front wall 4d, and rear wall 4e. The top wall 4b of the first casing 4 has a keyboard mounting area 5 and a projection 6. A keyboard 7 is set in the keyboard mounting area 5. The projection 6 projects upward from the rear end portion of the top wall 4b and extends in the width direction of the first casing 4. The projection 6 has a pair of display support portions 8a and Bb, which are spaced in the width direction of the first casing 4.

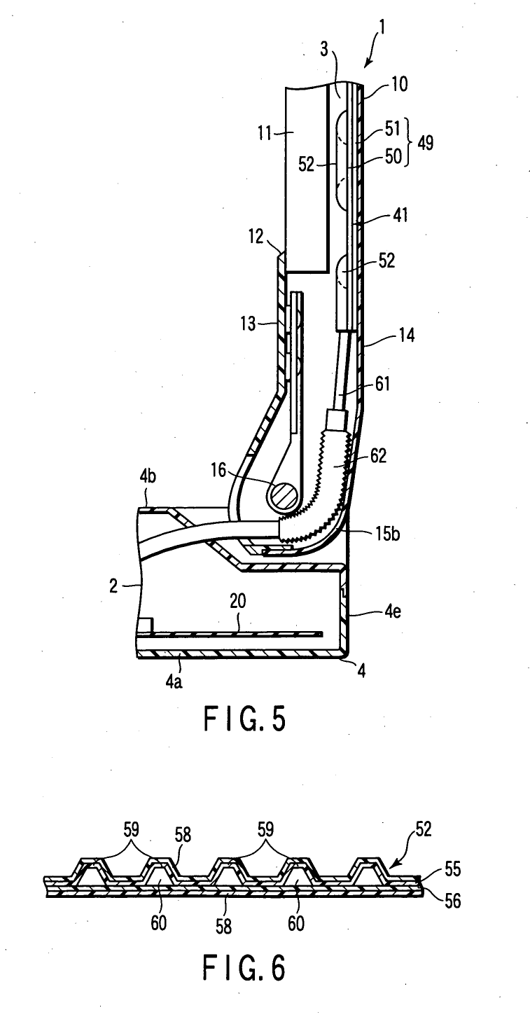

As shown in FIGS. 1 and 5, the display unit 3 is provided with a display housing 10 for use as a second casing and a liquid crystal display panel 11 that is set in the housing 10. The display housing 10 is formed of a thermally conductive plastic material. The display housing 10 is a flat box that has a front wall 13, in which a display window 12 is formed, and a rear wall 14 for use as an outer wall. The rear wall 14 is opposed to the display window 12 and the front wall 13. The liquid crystal display panel 11 has a display screen (not shown) that displays characters and images. The display screen is exposed to the outside of the display housing 10 through the display window 12.

As shown in FIGS. 1 and 2, the display housing 10 has a pair of legs 15a and 15b that protrude from its one end portion. The legs 15a and 15b are hollow and spaced in the width direction of the display housing 10. The legs 15a and 15b are fitted in the display support portions 8a and 8b, respectively, of the first casing 4. The one leg 15a is rockably connected to the one display support portion 8a, while the other leg 15b is connected to the first casing 4 by means of a hinge unit 16.

Thus, the display unit 3 is rockable between a closed position where it is leveled to overlie the keyboard 7 and an open position where it rises behind the keyboard 7. The first casing 4 and the second casing constitute a casing according to the present invention.

As shown in FIGS. 2 to 5, the first casing 4 contains a circuit board 20 for use as a system substrate. A semiconductor package 21 (circuit component), which is a heat-generating component, is mounted on the upper surface of the circuit board 20. The package 21 constitutes a microprocessor that serves as the CPU for the portable computer 1. The package 21 has a rectangular base 22 and an IC chip 23 that is soldered to the upper surface of the base 22. Owing to its increased processing speed and multifunctional performance, the IC chip 23 generates very high heat during operation. Thus, maintenance of its stable operation requires cooling.

As shown in FIG. 2, the portable computer 1 is mounted with a liquid-cooling unit 25 for cooling the semiconductor package 21. The cooling unit 25 is provided with a heat receiving head 26 that serves as a heat receiving portion, a radiator 52 that serves as a heat radiating portion, a circulation path 54, and a centrifugal pump 63. The pump 63 serves as circulating means for circulating a liquid coolant through these elements.

The heat receiving head 26 is located in the first casing 4 and thermally connected to the semiconductor package 21. More specifically, the head 26 has a heat conduction case 27, which is a flat box having a plane configuration greater than that of the semiconductor package 21, as shown in FIGS. 2 to 4.

The heat conduction case 27 is composed of a passage plate 28 and a flat lid plate 30. The passage plate 28 has a recess that is formed by pressing, etching, or cutting. The lid plate 30 is superposed and fixed on the passage plate 28 by welding, brazing, or adhesive bonding. The passage plate 28 and the lid plate 30 have the same external shape. A plurality of fins 32 are arranged parallel to one another at spaces in the recess of the passage plate 28. Thus, a plurality of circulation passages 33 are defined side by side in parallel relation in the heat conduction case 27. This configuration can realize a thin heat receiving portion. Although the lid plate 30 is a flat plate, the outer surface thereof may be formed having-irregularities.

The heat conduction case 27 has a coolant inlet port 34 and a coolant outlet port 35. The coolant inlet port 34 opens in the sidewall portion of the case 27 and communicates with the respective upper-stream ends of the circulation passages 33. The coolant outlet port 35 opens in the sidewall portion of the case 27 and communicates with the respective lower-stream ends of the circulation passages 33.

On the opposite sides of the coolant inlet port 34, a pair of first slits 36 are formed in the sidewall portion of the heat conduction case 27. These first slits 36 constitute a first junction 37 to which a pipe joint can be connected. A first pipe joint 45 is fitted in the first slits 36 of the first junction 37 and communicates with the coolant inlet port 34.

On the opposite sides of the coolant outlet port 35, a pair of second slits 38 are formed in the sidewall portion of the heat conduction case 27 in like manner. These second slits constitute a second junction 39 to which a pipe joint can be connected. A second pipe joint 46 is fitted in the second slits 38 of the second junction 39 and communicates with the coolant outlet port 35.

By forming the first and second slits 36 and 38 in this manner, the first and second junctions 37 and 39 can be formed directly on the heat conduction case 27. Accordingly, the configuration of the heat receiving head 26 can be made simpler than in the case where a separate junction is fixed to the heat conduction case by adhesive bonding or welding. Thus, the manufacturing cost can be lowered, and the heat receiving head can be thinned.

The heat conduction case 27 constructed in this manner is pressed against the IC chip 23 of the semiconductor package 21 by means of a cross-shaped plate spring 40. The case 27 is positioned with respect to the semiconductor package 21 by four screws 41. Apertures 42 are formed individually in the four corner portions of the heat conduction case 27. An aperture 43 is formed in the distal end of each of arm portions of the spring 40. A sleeve-type spacer 44 is passed through each of the apertures 42 and 43. Each screw 41 is passed through a spacer 44 from above and fastened to the circuit board 20. Thus, the central portion of the spring 40 elastically presses the heat conduction case 27 against the IC chip 23 under desired pressure.

The bottom wall of the heat conduction case 27 forms a flat heat receiving surface 27a. The surface 27a is in contact with the IC chip 23 of the semiconductor package 21 with a heat conduction sheet 48 between them. Thus, the case 27 is thermally connected to the chip 23 through the sheet 48.

According to the present embodiment, as shown in FIG. 4, a plate 50 with high heat conductivity is embedded in the heat receiving surface 27a of the heat conduction case 27. If the passage plate 28 of the case 27 is formed of a material with relatively low heat conductivity, such as SUS304, which cannot be easily corroded by water for use as a liquid coolant, the temperature distribution in the longitudinal direction of each fin 32 in the heat receiving head 26 is uneven. Therefore, it is difficult to effectively use all the fins 32 to cool the liquid coolant. Dispersion of the temperature distribution in the longitudinal direction of each fin 32 can be lessened by embedding a high-conductivity plate material, such as copper, aluminum, or aluminum nitride, in the heat receiving surface 27a. Thus, the heat receiving head 26 with a high heat transfer capability can be obtained without failing to prevent corrosion by the liquid coolant. Although the fins 32 are formed of SUS304 that has relatively low heat conductivity, in this case, their influence can be reduced by lessening their height (in the direction perpendicular to the passage plate 28). In consequence, the fins 32 hardly cause the heat transfer capability of the heat receiving head 26 to lower.

As shown in FIGS. 2, 5 and 6, the radiator 52 of the cooling unit 25 is set in the display housing 10 and interposed between the rear wall 14 of the housing 10 and the liquid crystal display panel 11. The radiator 52 is in the form of an oblong plate that is substantially equal to the panel 11 in size. The radiator 52 is provided with first and second radiating plates 55 and 56. The first and second radiating plates 55 and 56 are formed of a plastic material, such as polypropylene that combines heat conductivity with thermal resistance. The radiating plates 55 and 56 are superposed on each other, and their respective outer peripheral edges are integrally coupled by thermal welding throughout the circumference. A plastic surface layer 58 for liquid leakage prevention covers the respective outer surfaces of the first and second radiating plates 55 and 56. The plates 55 and 56 may be formed of a metallic material with high heat conductivity such as aluminum alloy, copper, or magnesium.

The first radiating plate 55 is rugged and has bulges 59 that project on the side opposite from the second radiating plate 56. The bulges 59 are formed substantially over the whole surface of the first radiating plate 55 and open to the joint surface of the second radiating plate 56. The flat second radiating plate 56 closes the respective open ends of the bulges 59. The bulges 59 define a circulation passage 60 over the second radiating plate 56. The bulges 59 are formed having a designed pattern, which will be mentioned later.

Behind the liquid crystal display panel 11, the radiator 52 is fixed to the rear wall 14 of the display housing 10 by fitting, adhesive bonding, or screwing. The surface layer 58 is sandwiched between the second radiating plate 56 and the rear wall 14. Thus, the radiator 52 is connected thermally to the display housing 10.

As shown in FIG. 2, the radiator 52 has a coolant inlet port 62 and a coolant outlet port 64. The inlet 62 is continuous with the upper-stream end of the circulation passage 60 and is situated at the left-hand end portion of the radiator 52. It adjoins the left-hand leg 15a of the display housing 10. The outlet 64 is continuous with the lower-stream end of the passage 60 and is situated at the right-hand end portion of the radiator 52. It adjoins the right-hand leg 15b of the housing 10. Thus, the inlet 62 and the outlet 64 are spaced in the width direction of the display housing 10.

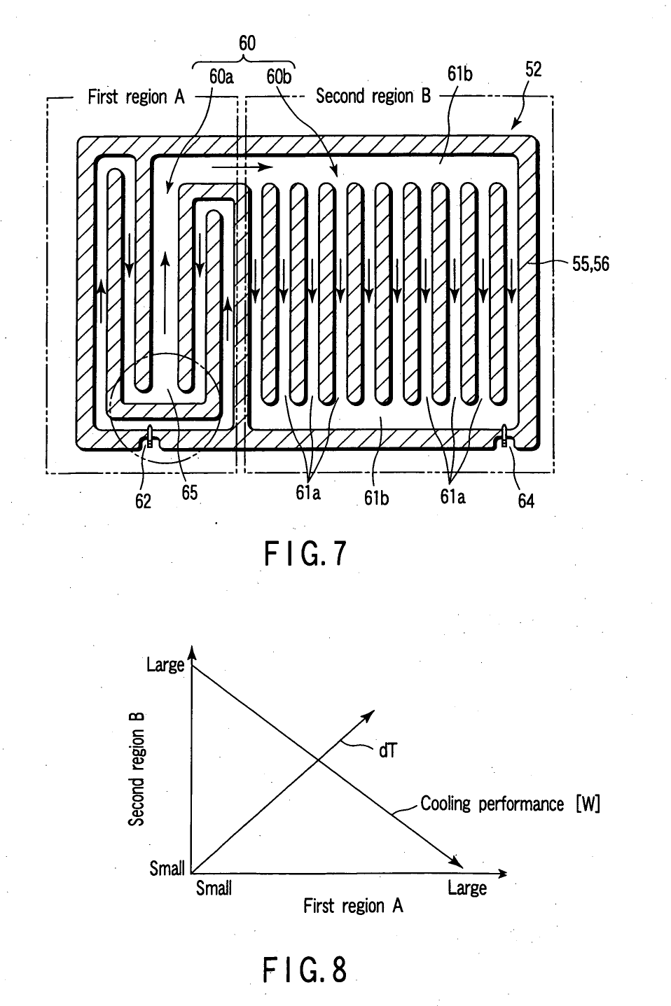

The following is a description of the configuration of the circulation passage 60 of the radiator 52. As shown in FIG. 7, the radiator 52 has two regions, a first region A that covers the coolant inlet port 62 and a second region B that covers the coolant outlet port 64. The passage 60 has a first circulation passage 60a in the first region A and a second circulation passage 60b in the second region B.

After the first circulation passage 60a diverges left and right from the coolant inlet port 62, the resulting branches extend in the height direction of the display housing 10 to positions distant enough from the coolant inlet port 62, and join again in a position 65 near the inlet 62. Then, the first circulation passage 60a extends again in the height direction of the housing 10 from the position 65 near the inlet 62 to a position distant from the inlet 62, thereby reaching the second region B.

The second circulation passage 60b substantially covers the whole area of the second region B. It is composed of a plurality of branch passages 61a, which extend in the height direction of the display housing 10 and are situated in parallel with one another, and two manifold-shaped passages 61b, which extend individually on the opposite sides of the branch passages 61a. The second circulation passage 60b extends from the first circulation passage 60a to the coolant outlet port 64.

According to the radiator 52 constructed in this manner, the liquid coolant introduced into the radiator 52 through the coolant inlet port 62 flows through the first circulation passage 60a in the first region A. After its temperature is lowered in some measure by heat radiation, the liquid coolant exchanges heat with the liquid coolant in the passage in the position 65 near the coolant inlet port 62. Thus, the maximum value of the liquid coolant temperature attained in the position 65 near the coolant inlet port 62 can be restrained. If the value of heat release from the semiconductor package 21 is about 30 W, for example, the temperature of the liquid coolant that flows into the coolant inlet port 62 of the radiator 52 may reach about 60° C., in some cases. If the first circulation passage 60a of the radiator 52 is constructed in the aforesaid manner, however, the liquid coolant near the coolant inlet port 62 can be cooled to, for example, a temperature lower than 50° C., that is the heat resisting temperature of the liquid crystal display panel 11.

If the radiator 52 and the first and second radiating plates 55 and 56 are formed of a resin or the like that has low heat conductivity, the effect of restraining the maximum value of the liquid coolant temperature can be promoted by providing a high-conductivity metallic plate near the coolant inlet port 62.

The area ratio between the first and second regions A and B of the radiator 52 is set in accordance with the necessary cooling performance of the radiator 52. If the area of the first region A is increased, as shown in FIG. 8, the general cooling performance of the radiator 52 lowers correspondingly, although the maximum value of the liquid coolant temperature near the coolant inlet port 62 can be restrained. In FIG. 8, dT represents the difference between the liquid coolant temperature near the coolant inlet port 62 and the liquid coolant temperature near the coolant outlet port 64. Thus, the maximum value of the liquid coolant temperature is adjusted to a level not higher than a given temperature, and the first and second regions A and B are freely set in a ratio such that a desired cooling capacity can be obtained. The respective shapes of the first and second regions A and B are not limited to the rectangular ones shown in FIG. 7, and may be selected variously depending on the design.

As shown in FIGS. 2, 4 and 5, the circulation path 54 of the cooling unit 25 is provided with first and second circulation pipe 66 and 68. The pipes 66 and 68 bestride the boundary between the first casing 4 and the display housing 10.

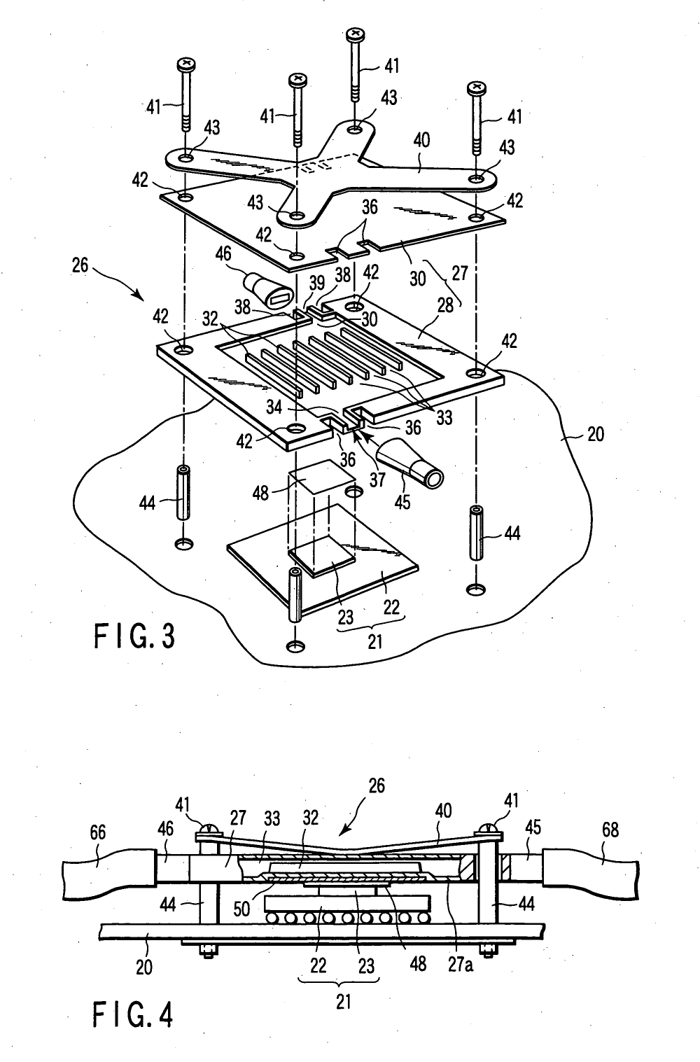

The first circulation pipe 66 connects the coolant outlet port 35 of the heat receiving head 26 and the coolant inlet port 62 of the radiator 52. After the pipe 66 is guided through the interior of the first casing 4 toward the left-hand display support portion 8a, it is introduced into the display housing 10 through the support portion 8a and the left-hand leg 15a. As shown in FIGS. 3 and 4, the first circulation pipe 66 is connected to the second junction 39 of the heat receiving head 26 by means of the second pipe joint 46.

The second circulation pipe 68 connects the coolant inlet port 34 of the heat receiving head 26 and the coolant outlet port 64 of the radiator 52. After the pipe 68 is guided through the interior of the first casing 4 toward the right-hand display support portion 8b, it is introduced into the display housing 10 through the support portion 8b and the right-hand leg 15b. As shown in FIGS. 3 and 4, the second circulation pipe 68 is connected to the first junction 37 of the heat receiving head 26 by the first pipe joint 45.

Thus, the circulation passages 33 in the heat receiving head 26 and the circulation passage 60 in the radiator 52 are connected to one another by means of the first and second circulation pipes 66 and 68. The liquid coolant is sealed in the circulation passages 33 and 60 and the circulation pipes 66 and 68. The liquid coolant may be water or an antifreeze solution formed of water doped with ethylene glycol, for example.

As shown in FIGS. 2 and 5, those parts of the first and second circulation pipes 66 and 68 which are introduced into the legs 15a and 15b of the display housing 10 are formed of a flexible bellows tube 70 each. When the display unit 3 is rocked toward the closed or open position, the bellows tube 70 is smoothly deformed to absorb bending force that acts on each of the first and second circulation pipes 66 and 68 as the unit 3 rocks.

The centrifugal pump 63 is connected to the middle portion of the second circulation pipe 68 and held in the first casing 4. The pump 63 is actuated when it is connected to the power supply or when the semiconductor package 21 is heated to a predetermined temperature. It causes the liquid coolant to circulate through the circulation path 54.

In the portable computer 1 constructed in this manner, the IC chip 23 of the semiconductor package 21 generates heat during the operation of the computer. The heat from the chip 23 is transmitted to the heat receiving surface 27a of the heat receiving head 26. Since the head 26 has the circulation passages 33 in which the liquid coolant is sealed, the liquid coolant absorbs much of the heat transmitted to the surface 27a.

When the temperature of the semiconductor package 21 reaches a given value, the centrifugal pump 63 starts to operate. Thereupon, the liquid coolant is forced out from the heat receiving head 26 toward the radiator 52 and compulsorily circulated between the circulation passages 33 of the head 26 and the circulation passage 60 of the radiator 52.

Thus, the liquid coolant heated by heat exchange in the heat receiving head 26 is pressurized by means of the centrifugal pump 63 and guided into the radiator 52 through the first circulation pipe 66. The liquid coolant enters the radiator 52 through the coolant inlet port 62, flows through the circulation passage 60, and is guided to the coolant outlet port 64. The heat from the IC chip 23 that is absorbed by the liquid coolant in the process of this flow is diffused into the first and second radiating plates 55 and 56, and discharged from the surface of the radiator 52 into the display housing 10. In consequence, the heated liquid coolant is cooled by heat exchange in the radiator 52.

As mentioned before, the liquid coolant first passes through the first circulation passage 60a and flows in the first region A of the radiator 52. After it is temporarily cooled, the liquid coolant is returned to the position 65 near the coolant inlet port 62, and exchanges heat with the liquid coolant near the coolant inlet port. Thus, the liquid coolant temperature that has its maximum near the coolant inlet port 62 is lowered. Thereafter, the liquid coolant passes through the second circulation passage 60b, flows in the second region B of the radiator 52, and is cooled by heat exchange in the radiator.

The liquid coolant that is cooled as it passes through the radiator 52 flows through the second circulation pipe 68, and is returned to the circulation passages 33 of the heat receiving head 26 by the centrifugal pump 63. After the liquid coolant absorbs the heat from the IC chip 23 again as it flows through the circulation passages 33, it is guided to the radiator 52. As this cycle is repeated, the heat form the IC chip 23 is discharged to the outside of the portable computer 1 through the display unit 3.

According to this configuration, the radiator 52 is set in the display housing 10 of the display unit 3, and the liquid coolant is circulated between the radiator 52 and the heat receiving head 26 that receives heat from the semiconductor package 21. Therefore, the heat from the package 21 can be efficiently transferred to the display unit 3 by utilizing the liquid coolant flow and then discharged into the atmosphere. Thus, the heat radiation performance of the semiconductor package 21 can be enhanced considerably as compared with the case of conventional forced air-cooling.

According to the embodiment described above, the radiator 52 has the first region A that includes the coolant inlet port 62 and the second region B that includes the coolant outlet port 64. The liquid coolant temperature near the coolant inlet port 62 is lowered by running the liquid coolant through the first circulation passage 60a in the first region A. Further, the liquid coolant is cooled by radiating heat as it is run through the second circulation passage 60b in the second region B. According to the radiator 52 constructed in this manner, the maximum value of the liquid coolant temperature attained in the position near the coolant inlet port 62 can be restrained. If the value of heat release from the semiconductor package 21 is about 30 W, for example, the temperature of the liquid coolant that flows into the coolant inlet port 62 of the radiator 52 reaches about 60° C. If the first circulation passage 60a of the radiator 52 is constructed in the aforesaid manner, however, the liquid coolant near the coolant inlet port 62 can be cooled to, for example, a temperature lower than 50° C., the heat resisting temperature of the liquid crystal display panel 11. Even if the radiator 52 is located adjacent to the liquid crystal display panel 11 in the display housing 10, therefore, the display panel 11 can be prevented from being thermally damaged by the radiator 52. Thus, the package 21 can be efficiently cooled, and the reliability of the portable computer 1 can be improved.

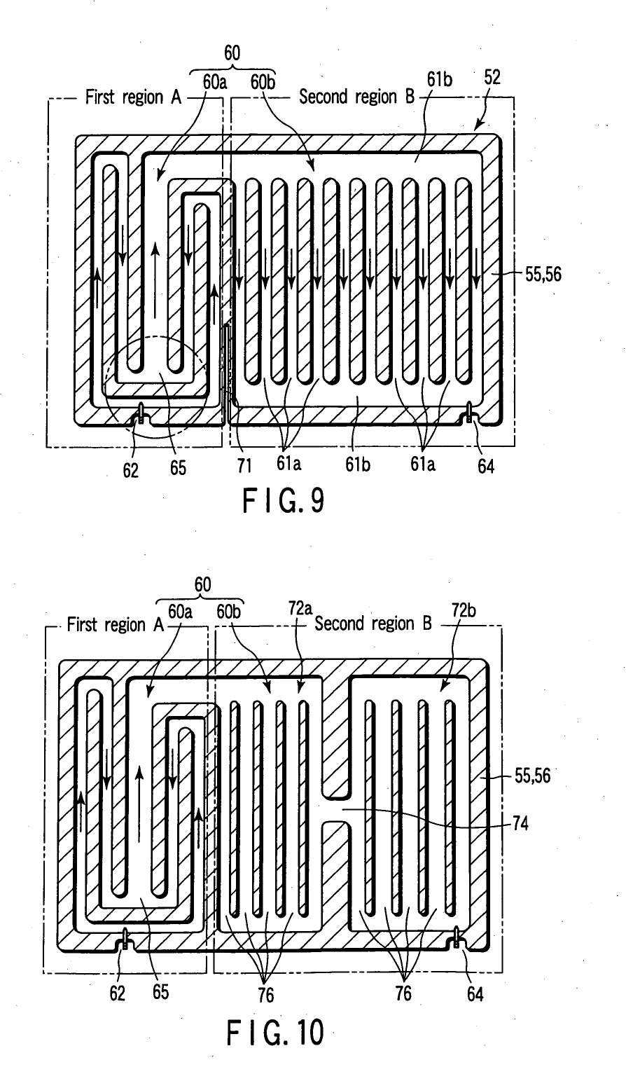

The present invention is not limited to the first embodiment described above, and various changes and modifications may be effected therein without departing from the scope or spirit of the invention. According to the first embodiment, heat is not fully radiated from the liquid coolant that flows through the first circulation passage 60a in the first region A of the radiator 52, so that the liquid coolant is at a relatively high temperature. On the other hand, the liquid coolant that flows through the passages 61b on the lower-stream side of the circulation passage 60 in the second region. B has its heat fully radiated and is at a low temperature. In a portable computer according to a second embodiment of the invention, as shown in FIG. 9, first and second radiating plates 55 and 56 that constitute a radiator 52 are formed having a slit 71 that extends between first and second regions A and B. The slit 71 serves to prevent heat exchange between a higher-temperature portion of the liquid coolant that flows through the first region A and a lower-temperature portion of the liquid coolant that flows through the second region B. Thus, the liquid coolant can radiate heat more efficiently in the second region of the radiator 52, and so that the cooling performance can be improved.

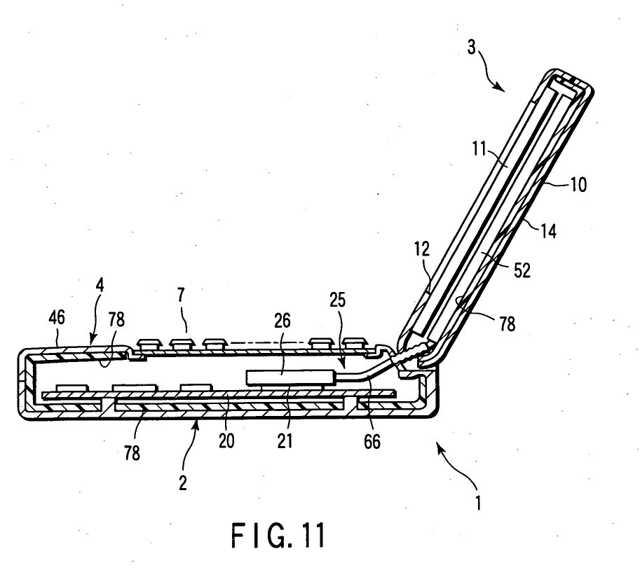

According to a third embodiment shown in FIG. 10, a second circulation passage 60b in a second region B of a radiator 52 is composed of a plurality of branch portions 72a and 72b (e.g., two in number) that are arranged side by side and one connecting passage 74 that connects the branch portions 72a and 72b. Each of the branch portions 72a and 72b has a plurality of branch passages 76 that extend parallel to one another.

If the two branch portions 72a and 72b are connected through the single connecting passage 74, load that acts on the centrifugal pump 63 can be made lighter than in the case where one second circulation passage is laid spirally. Thus, the power consumption of the portable computer can be lessened without lowering the cooling capacity.

According to the cooling system described above, on the other hand, a liquid coolant, such as water or an antifreeze solution, circulates in the portable computer 1, so that it may leak out into the casing. According to a fourth embodiment shown in FIG. 11, therefore, the respective inner surfaces of a first casing 4 and a display housing 10 are provided with a water absorbing material. In this case, a water absorbing polymer sheet 78 is used as the water absorbing material. The polymer sheet 78 is stuck substantially to the whole area of the respective inner surfaces of the first casing 4 and the housing 10.

The water absorbing material need not always cover the whole surface of the housing, and is expected only to be provided at least on the inner surface of the housing near the pipe joints, near the heat receiving head 26 and the radiator 52, or near the circulation pipes. Besides the water absorbing polymer sheet, water absorbing paper or the like may be used as the water absorbing material. Further, the water absorbing material need not always be a sheet, and may be a gel that is spread over the inner surface of the casing.

Even if the liquid coolant leaks from the cooling unit 25 into the first casing 4 or the display housing 10, according to the configuration described above, the water absorbing polymer sheet 78 can absorb and keep the leaked liquid coolant therein. Accordingly, the possibility of the leaked liquid coolant touching and damaging electronic components in the portable computer 1 can be lowered considerably. At the same time, the leaked liquid coolant can be prevented from leaking out of the computer 1.

The second to fourth embodiments share other configurations with the first embodiment. Therefore, like reference numerals are used to designate like portions throughout the drawings, and a detailed description of those portions is omitted. Any of the second to fourth embodiments can produce the same effects of the first embodiment. Further, each of the first to fourth embodiments may be combined with any other embodiment or embodiments.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

For example, the present invention is not limited to portable computers, and it is also applicable to any other electronic apparatus, such as a desktop computer. In this state, the electronic apparatus is not limited to one that is provided with first and second casings, and may be one that is provided with only one casing. Further, the positions of the components of the cooling unit may be changed as required. For example, the centrifugal pump may be provided in the second casing. Furthermore, the radiator may be provided together with the heat receiving portion in the first casing instead of the second casing.

1-7. (canceled)

8. An electronic apparatus comprising:
a casing;
a heat-generating component arranged in the casing;
a heat receiving portion located in the casing and thermally connected to the heat-generating component, the heat receiving portion having a circulation passage defined therein;
a heat radiating portion configured to radiate heat generated by the heat-generating component, the heat radiating portion being arranged in the casing and having a circulation passage defined therein;
a circulation path which circulates a liquid coolant between the circulation passage in the heat receiving portion and the circulation passage in the heat radiating portion; and
a liquid absorbing material arranged on an inner surface of the casing.

9. An electronic apparatus according to claim 8, wherein the liquid absorbing material substantially covers the whole inner surface of the casing.

10. An electronic apparatus comprising:
a first casing;
a heat-generating component arranged in the first casing;
a heat receiving portion located in the first casing and thermally connected to the heat-generating component, the heat receiving portion having a circulation passage defined therein;
a second casing connected to the first casing;
a heat radiating portion configured to radiate heat generated by the heat-generating component, the heat radiating portion being arranged in the second casing and having a circulation passage defined therein;
a circulation path to circulate a liquid coolant between the circulation passage in the heat receiving portion and the circulation passage in the heat radiating portion; and
a liquid absorbing material arranged on the inner surface of at least one of the first and second casings.

11. An electronic apparatus according to claim 10, wherein the liquid absorbing material substantially covers the whole inner surfaces of the first and second casing.

12. An electronic apparatus according to claim 10, wherein the liquid absorbing material includes a water absorbing polymer sheet.

13-15. (canceled)
